(19) United States
(12) Patent Application Publication
(10) Pub. No.: US 2013/0141259 A1
(43) Pub. Date: Jun. 6, 2013

(54) METHOD AND SYSTEM FOR DATA COMPRESSION

(71) Applicant: Samsung Electronics Co., Ltd., Gyeonggi-do (KR)

(72) Inventors: Debabrata HAZARIKA, Bangalore (IN); Piyush Kumar Rai, Bangalore (IN); Samarth Vinod Deo, Bangalore (IN); Srinivas Karlapudi, Bangalore (IN)

(73) Assignee: Samsung Electronics Co., Ltd., Gyeonggi-do (KR)

(21) Appl. No.: 13/705,694

(22) Filed: Dec. 5, 2012

(30) Foreign Application Priority Data
Dec. 5, 2011 (IN) 4237/CHE/2011

(51) Int. Cl. H03M 7/30

(52) U.S. Cl. CPC H03M 7/3059
USPC 341/106

(57) ABSTRACT

A method and system for effective pattern compression are provided. The method includes selecting a Minimal Perfect Hashing Function (MPHF); identifying a base character set for which the MPHF is designed; identifying characters of a target character set; and applying scrambling to distribute the characters of the target character set over the base character set.

### PRIORITY

This application claims priority under 35 U.S.C. §119(a) to a Indian Patent Application filed in the Indian Patent Office on Dec. 5, 2011 and assigned Serial No. 4237/CHE/2011, the entire content of which is incorporated herein by reference.

### BACKGROUND OF THE INVENTION

1. Field of the Invention

The present invention relates generally to data compression and, more particularly, to compression of digital data independent of input data-set characteristics.

2. Description of the Related Art

Data compression is the process of encoding data/information such that resulting representation has fewer bits than the original representation of the data/information (i.e., storing data in a format that occupies less space than usual). Compression is useful in communications, as compression enables devices to transmit or store the same amount of data in fewer bits. Performing compression includes using an encoding algorithm that takes a message and generates a “compressed” representation.

Data compression is widely used in backup utilities, spreadsheet applications, and database management systems. Using data compression, certain types of data, such as bit-mapped graphics, can be compressed to a small fraction of their normal size.

However, the compressed data must be decompressed to be used. A decoding module that reconstructs the original data or some approximation of the original data from the compressed representation is required at the output. The extra processing required to perform the uncompression is detrimental to certain applications.

The design of data compression schemes therefore involves trade-offs among various factors, including the degree of compression, the amount of distortion introduced and the computational resources required to compress and uncompress the data.

Data compression is mainly classified into two categories, namely, lossless compression and lossy compression. Lossless compression is reversible so that the original data can be reconstructed, whereas lossy data compression schemes accept some loss of data so as to achieve higher compression. Lossless data compression schemes are implemented in cases where the data to be compressed includes information such as text, executable programs, etc. In these examples data for which lossless data compression is applied, loss of even a single bit cannot be tolerated. By performing compression, large amount of storage space can be saved. Data compression is achieved using data compression algorithms. Different algorithms are be used to perform compression depending upon the type of data compression to be achieved.

Present technologies enable data compression by utilizing various algorithms such as Huffman's coding, arithmetic coding, Dictionary based/Substitutional algorithm, dynamically generated dictionaries and so on. The dictionaries can improve data compression ratios of data with complex data types, frequent data changes or/and data values without obvious boundaries.

Most conventional compression technologies are for compressing data constituting words in a particular language (mainly English). Hence, present technologies are not very efficient in data compression of words/text/pattern of other languages or character sets. Most of the known compression algorithms work on discovering the redundancies in the set of words, where redundancy itself is created through the periodicity of patterns. This reduces the chances of finding redundancy where the set itself is made of those patterns.

In many text prediction and Information Retrieval (IR) systems, it is necessary to lookup an input word in a given dictionary. The dictionary lookup algorithm is thus crucial to the performance of these applications. The data-set that forms the dictionary often involves a huge number of text/patterns etc.

A dictionary can be organized as two sets of strings with the keys in the first set and the data in the second. Further, the keys are enumerated in such that the number associated with each key can be used to access the appropriate entry in the data set. Minimal Perfect Hash Functions (MPHF), Minimized Deterministic Finite Automata (MDFA), and tries are utilized to represent static lexicons and enumerated lexicons. With the help of MPHF, the unique number for each input key can be determined with a constant amount of time used for each determination. Hash functions, for example, provide the advantage of constant retrieval time and size.

A trie is a tree where paths from the roots to leaves correspond to input words. The trie for a set of words is a tree in which each transition represents one symbol (or a letter in a word), and nodes represent a word or a part of a word that is spelled by traversal from the root to the given node. The identical prefixes of different words are therefore represented with the same node. This trie system eliminates the redundancies being created due to repetitive prefixes in the form of identical patterns from the set of words. Moreover, a lookup of a word in a trie requires as many comparisons as there are symbols in a word.

The compression using a trie is based on exploiting the sparseness immanent to complete tries for big key sets. A trie built with only one character per transition is known as character trie.

While trie compression may be a viable option for compressing a set of full length words, it may not produce desired results when it comes to compressing a set of patterns being created out of words; the most prominent reason being the peculiarities of patterns as patterns might itself from the required redundancies among the set of full length words.

The execution time for the lookup of an input word in a compressed trie depends on the length of an input word. Thus, for problems that involve lookup of a word in a dictionary, hash tables (with O(1) lookup complexity) prove to be a better option with a known execution time, rather than using a trie structure.

A trie can be minimized by utilizing hash functions. Hashing is a well known technique for mapping data elements into a hash table by using a hash function to process the data for determining an address in the hash table. Hashing algorithms typically perform a sequence of probes into the hash table, where the number of probes varies per query.

A perfect hash function for a specific set S can be evaluated in constant time, and with values in a small range, can be found by a randomized algorithm in a number of operations that is proportional to the size of S. The minimal size of the description of a perfect hash function depends on the range of its function values: The smaller the range, the more space is required. Using a perfect hash function is best in situations where there is a set, S, that is not updated frequently, and is subject to many lookup operations.

There are numerous implementations of static search sets. Common examples include sorted and unsorted arrays and linked lists, digital search tries, deterministic finite-state automata, and various hash table schemes. Different static search structure implementations offer trade-offs between memory utilization and search time efficiency and predictability. For example, an n element sorted array is space inefficient. However, the average and worst-case time complexity for retrieval operations using binary search on a sorted array is proportional to O (log n). In contrast, hash table implementations locate a table entry in constant (i.e., O (1) time on the average. However, hashing schemes typically incur additional memory overhead in terms of empty locations etc.

Further, compression schemes using the aforementioned technologies have lower efficiency, have a higher runtime complexity involved, and require more memory than other data compression schemes.

### SUMMARY OF THE INVENTION

Accordingly, the present invention has been designed to address the above and other problems occurring in the prior art, and provide at least the advantages described below.

The principal aspect of the present invention is to provide a minimal hashing scheme, which overcomes the drawbacks of existing hash schemes and enables automated compression of data independent of input data character set or pattern.

Another aspect of the invention is to enable calculation of auxiliary data to minimize false positives.

According to an aspect of the present invention, a data compression method is provided. The method includes selecting a Minimal Perfect Hashing Function (MPHF); identifying a base character set for which the MPHF is designed; identifying characters of a target character set; and applying scrambling to distribute the characters of the target character set over the base character set. And the system comprises a compression unit for selecting a Minimal Perfect Hashing Function (MPHF); and a scrambler for identifying a base character set for which the MPHF is designed, identifying characters of a target character set, and distributing the characters of the target character set over the base character set.

According to another aspect of the present invention, a data compression system is provided. The system includes a compression unit for selecting a Minimal Perfect Hashing Function (MPHF); and a scrambler for identifying a base character set for which the MPHF is designed, identifying characters of a target character set, and distributing the characters of the target character set over the base character set.

### BRIEF DESCRIPTION OF THE VIEW OF THE DRAWINGS

The above and other aspects, features and advantages of the present invention will be more apparent from the following detailed description taken in conjunction with the accompanying drawings, in which:

FIG. 1 is a block diagram illustrating networking arrangement for data compression, according to an embodiment of the present invention;

FIG. 2 is a block diagram illustrating architecture of a compression unit, according to an embodiment of the present invention;

FIG. 3 is a flow chart illustrating a process of hashing the characters of target language based on their frequency of occurrence, according to an embodiment of the present invention;

FIG. 4 is a table illustrating the frequency table of characters in a target language based on their usage in set S, according to an embodiment of the present invention;

FIG. 5 is a flow chart illustrating a process of scrambling the characters of target language based on their frequency of occurrence, according to an embodiment of the present invention;

FIG. 6 is a diagram illustrating scrambling of a target language character set as a group of characters, according to an embodiment of the present invention;

FIG. 7 is a block diagram illustrating an architecture of an auxiliary data calculation model, according to an embodiment of the present invention; and

FIG. 8 is a flow chart illustrating a process of scrambling the characters of target language by utilizing auxiliary data, according to an embodiment of the present invention.

### DETAILED DESCRIPTION OF EMBODIMENTS OF THE PRESENT INVENTION

Embodiments of the present invention include a method and system for aggregating component carriers across frequency bands. Embodiments of the present invention are described in detail hereinafter with reference to the accompanying drawings. In the following description, the same drawing reference numerals may be used for the same or similar elements even in different drawings. Additionally, a detailed description of known functions and configurations incorporated herein may be omitted when such a description may obscure the subject matter of the present invention.

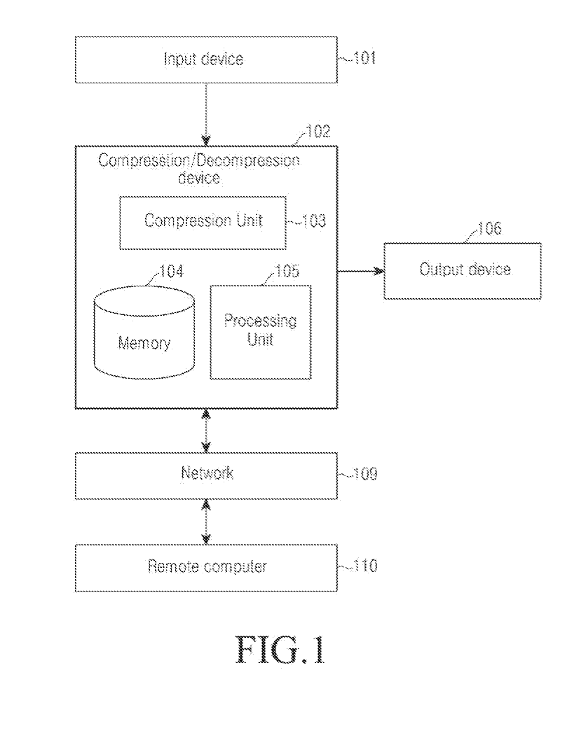

Embodiments of the present invention herein relate to a method and system for Block Acknowledgement mechanism for Multi-user transmissions. Referring now to the drawings, and more particularly to FIGS. 1 through 8, where similar reference characters denote corresponding features consistently throughout the figures, there are shown preferred embodiments.

Throughout the specification, the data/pattern compression has been explained with the help of linguistic string or language design pattern example. However, it should be noted that the data/pattern compression can be implemented even for non-linguistic design patterns in accordance with embodiments of the present invention.

A perfect hash usually refers to a hash function that maps elements into a hash table without any collisions. Generally, all the elements map to distinct slots of the hash table. The probability that randomly assigning n elements in a table of size m results in a perfect hash is given by Equation 1, where:

$${P}_{PH} ( n , m ) = ( 1 ) \cdot ( 1 - \frac{1}{m} ) \cdot ( 1 - \frac{2}{m} ) … ( 1 - \frac{n - 1}{m} ) \qquad ( 1 )$$

When the table is large (i.e., when m>>n), the probability of a perfect hash, pₚₕ, can be determined by using the approximation e^{x}≈1+x for small x, as illustrated by Equation 2, where:

$$\begin{matrix}{P}_{PH} ( n , m ) \approx 1 \cdot {e}^{- 1 / m} \cdot {e}^{- 2 / m} … {e}^{- ( n - 1 ) / m} \\ = {e}^{- ( 1 + 2 + … + n - 1 ) / m} \\ = {e}^{- ( n ( n - 1 ) / 2 m )} \\ \approx {e}^{- {n}^{2} / 2 m}\end{matrix} \qquad ( 2 )$$

Thus, the presence of a hash collision is highly likely when the table size m is much less than n².

FIG. 1 is a block diagram illustrating a networking arrangement for data compression, according to an embodiment of the present invention.

Referring to FIG. 1, a data compression device 102 according to an embodiment of the present invention includes a memory 104, a processing unit 105 and a compression unit 103. The memory 104 can store data of any format. The processing unit 105 fetches and processes the stored data. The processing unit 105 determines a character set of the input/target language data, an output/source language data, etc. The data can be transferred to the compression unit 103, where the data can be compressed to occupy less space. According to an embodiment of the present invention, the compression unit 103 can directly receive input data.

According to an embodiment, the target data can be received from any digital device, such as a mobile device, camera, database, memory, Personal Digital Assistant (PDA), scanner, Compact Discs (CDs) or Digital Versatile Discs (DVDs), etc. The compressed data can be stored in the memory of any digital device, at a server, or at another similar device.

According to another embodiment of the present invention, the compression unit 103 interacts with at least one remote computer 110 over a network 109, such as an Internet network. Further, the network 109 can be any wired or wireless communication network. The remote system is established to provide a target language over the network 109. The remote system includes at least one data centre. The compression unit 103 receives data from a data centre of the remote system over network 109. Further, the data can be delivered through e-mail from the remote unit to the compression unit over Internet for compression. The compression unit 103 compresses the target language. Further, the compressed data is delivered to the remote computer 110.

A good minimal hash function according to an embodiment of the present invention is a static search set implementation defined by the following two properties:

a) The perfect property: Locating a table entry requires O (1) time, i.e., at most one string comparison is required to perform keyword recognition within the static search set.

b) The minimal property: The memory allocated to store the keywords is precisely large enough for the keyword set and no larger.

The probability of finding a minimal hash (e.g., where n=m) is given by Equation 3, where:

$$\begin{matrix}{P}_{PH} ( n ) = ( \frac{n}{n} ) \cdot ( \frac{n - 1}{n} ) \cdot ( \frac{n - 2}{n} ) … ( \frac{1}{n} ) \\ = \frac{n !}{{n}^{n}} \\ = {e}^{( logn ! - nlogn )} \\ ≅ {e}^{( ( nlogn - n ) - nlogn )} \\ = {e}^{- n}\end{matrix} \qquad ( 3 )$$

The hash is constructed with a deterministic algorithm that takes O(n) time to reduce space complexity.

A trie based dictionary approach is used to store the words in a compressed manner by removing the redundancies created due to the repetition of patterns existing in words. The proposed minimal hashing technique is an effective technique to store the patterns in a compressed manner.

Good minimal hashing schemes provide the right framework for generating an effective lookup dictionary structure. Further, the attractiveness of using minimal hashing schemes, independent of the source language character set, depends upon following characteristics:

a) The properties of the character set for which the minimal hashing scheme has been designed.

b) Number of false-positives in case the minimal hashing scheme is used for a character set different from the one for which it is designed.

A new layer can be introduced above the minimal hashing scheme in order to make minimal hashing schemes independent of a character set, which essentially partitions the target language character set into groups of at least one character.

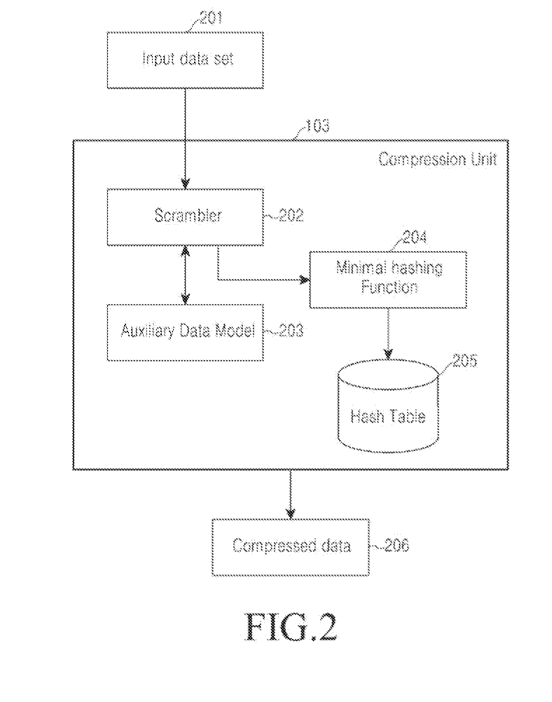

FIG. 2 is a block diagram illustrating an architecture of a compression unit, according to an embodiment of the present invention. The electronic circuitry of the compression unit of FIG. 2 can be implemented in any manner, for example, by software or firmware in a programmed digital computer or other digital signal processor, hardware implementations, and a combination thereof

Referring to FIG. 2, digital data, which may be news, trade information, financial information, historical data, trade data, quotes, or any other kind of data, is provided as input 201 to the compression unit 103. Further, the input data can be called a second/target language, which needs to be perfectly hashed. A scrambler 202 in the compression unit 103 divides the second/target language data into smaller data sets of at least one character. Further, the scrambler 202 includes a frequency calculation model that calculates the frequency of occurrence of each character of second (target) language from the set of words in set S. Further, the characters for each target language character can be distributed evenly based on their frequency of occurrence in a Minimal Perfect Hashing Function (MPHF) module 204. The scrambler 202 generates a 1: n mapping of base characters (the characters of the language for which an MPHF is designed) to the character set of second (target) language. MPHFs completely avoid the problem of wasted space and time. MPHFs can be used for memory efficient storage and fast retrieval of items from static sets, such as words in natural languages, reserved words in programming languages or interactive systems, Universal Resource Locators (URLs) in Web search engines, or item sets in data mining techniques. Furthermore, the target language character set mapped to the MPHF can be stored in a form a table in the memory. The table is a perfect hash table 205. The hash table assigns the data strips corresponding to each character set to an address in the perfect hash table 205.

Given a set of keys S, a hash function h : U→M is a perfect hash function for S if h is an injection on S, i.e., there are no collisions among the keys in S: if x and y are in S and x≠y, then h(x)≠h(y), where h is a hash function which computes an integer in [0, . . . , m-1] for the storage or retrieval of x in a hash table.

According to an embodiment of the present invention, the target language character set can be stored in the hash table 205 based on the frequency of the target language character set occurrences in order to achieve uniform distribution of 2nd (target) language character over that of first (source) language character, where the first (source) language base character-set is the character set in which MPHF has been designed.

Further, once the data has been compressed and stored in the hash table 205 of the memory, the compressed data can be transmitted to other locations or can be used in future.

FIG. 3 is a flow chart illustrating a process of hashing the characters of target language based on their frequency of occurrence, according to an embodiment of the present invention.

Referring to FIG. 3, the scrambler module receives the input target language, in step 301. The target language is divided into character set group S of at least one character for an even distribution of characters, in step 302. Further, the frequency calculation model calculates the frequency of occurrence of each character of 2nd (target) language from the set of words in set S, in step 303. The target language character set is then stored in a form a table based on the frequency of their occurrences, in step 304. The various actions in the method 300 can be performed in the order presented, in a different order, or simultaneously. Further, in some embodiments of the present invention, some actions listed in FIG. 3 can be omitted.

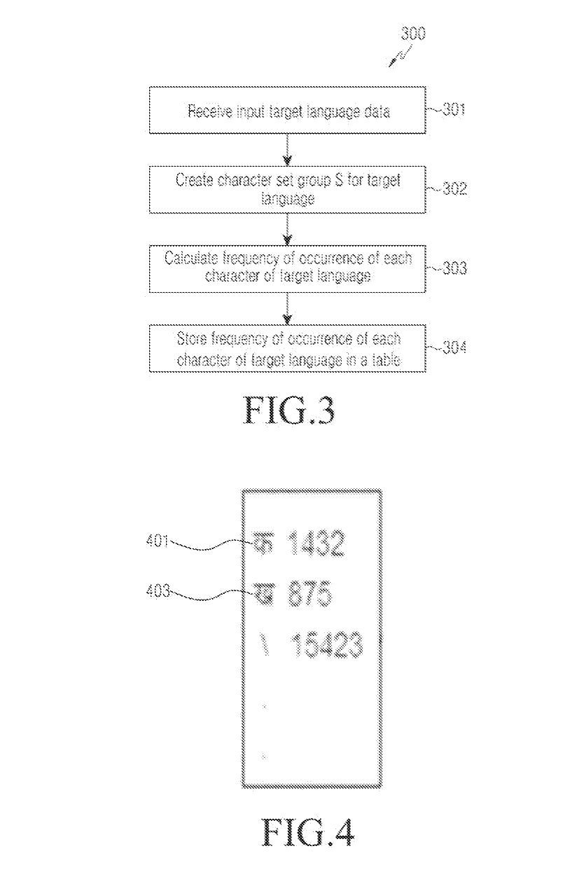

FIG. 4 is a diagram illustrating a frequency table of characters in a target language based on their usage in set S, according to an embodiment of the present invention.

Referring to FIG. 4, the target language may be Hindi, for example. The target language can be grouped into character sets. Further, frequency of each character from the set S can be determined as shown in FIG. 4. FIG. 4 illustrates an example where a first character 401 has an occurrence frequency of 1432 and a second character 403 has an occurrence frequency of 875.

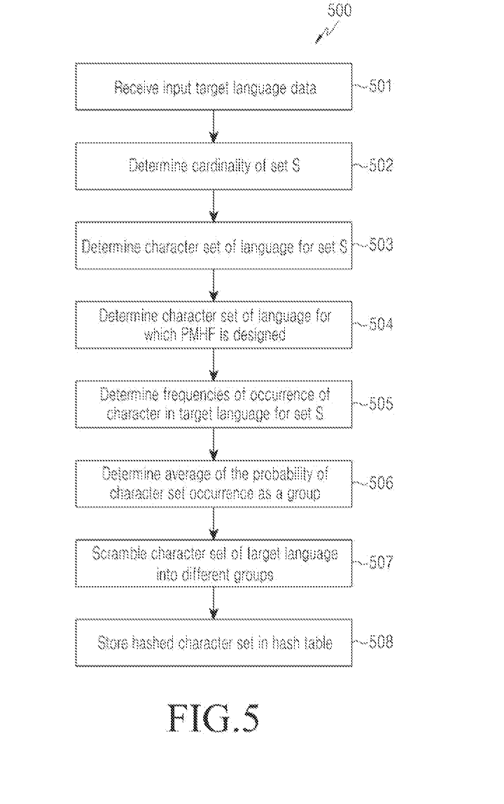

FIG. 5 is a flowchart illustrating a process of scrambling characters of a target language based on their frequency of occurrence, according to an embodiment of the present invention.

Referring to FIG. 5, the scrambler module 202 receives the input target language, is step 501. The target language can be divided into a character set group S of at least one character for even distribution of characters. Further, Cardinality of set S (i.e., the total number of words to be hashed) is determined, in step 502. Further, a character set of target language for set S is determined, in step 503. The character set of first (source) language for which MPHF is designed, is determined, in step 504. Further, the frequency of occurrence of characters in the target language for set S is determined, in step 505. The scrambler 202 then intelligently scrambles the characters constituting the elements in set S. The Scrambling of character set is performed by averaging out the combined probability of character set occurrences as a group based on the cardinality of set S, such that each group of characters formed out of 2nd language character set has an equal probability of occurrence, in step 506. The character set S of target language is scrambled into different groups corresponding to the character set of source language in which MPHF is defined, in step 507. Further, hashed character sets are stored in the hash table 205, in step 508. The MPHF is selected independently of the base character set and the target character set. The scrambling can be performed independently of the base character set and the target character set. The various actions in the method 500 can be performed in the order presented, in a different order, or simultaneously. Further, in some embodiments of the present invention, some actions listed in FIG. 5 can be omitted.

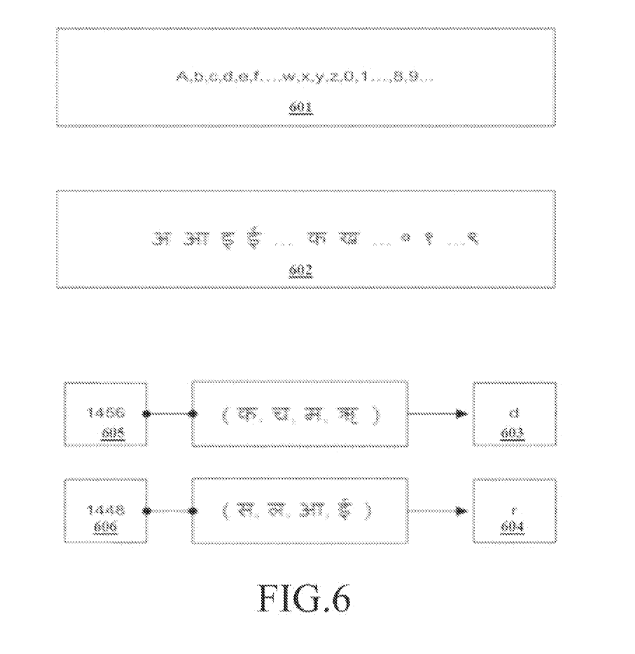

FIG. 6 is a diagram depicting scrambling of a target language character set as a group of characters, according to an embodiment of the present invention.

Referring to FIG. 6, Hindi is a target language 602 and English is a source language 601 input into a compression module. The target language 602 is divided into character set group S of at least one character. Further, Cardinality of set S, character set of target language for set S, character set of first (source) language for which MPHF is designed, can be determined. The character set of target language and source language in this case are 64 and 26 respectively. Further, the frequency of occurrence of characters in the target language for set S can be determined. The scrambler then scrambles the characters constituting the elements in set S. After scrambling of character set, the different characters from the target language character set form a group denoted by reference numerals 603 and 604, which represents a unique character from source language character set. Further, the averaged probability of occurrence for each group can be determined.

For example, the averaged probability of occurrence for each group may be set as shown with reference numerals 605 and 606. This arrangement evenly distributes the second language character set over the first language character set. The scrambler, maps the source characters to the character set of second (target) language and stores the mapped characters in hash table.

An MPHF is an extremely simple data structure for testing a membership of a word/patterns in set S; as it is often desirable to store a set of words/patterns having average lookup time as O(1). Further, the efficiency of any MPHF depends upon the number of false positives being generated for a particular data set.

The false positives can be generated when the hash values are identical for group of input words/patterns that do not belong to set S. The number of input words/patterns that have the same hash value is directly related to the size of the word/patterns and their peculiar characteristics.

According to another embodiment of the present invention, an auxiliary data calculation model can be utilized before hashing the character sets of target language. Defining an auxiliary data byte for each item in a data set S enables a reduction in the number of false positives. The auxiliary data byte can be calculated based on the characteristics of an item in the data set S that includes of number of bits in the string and length of the pattern/word.

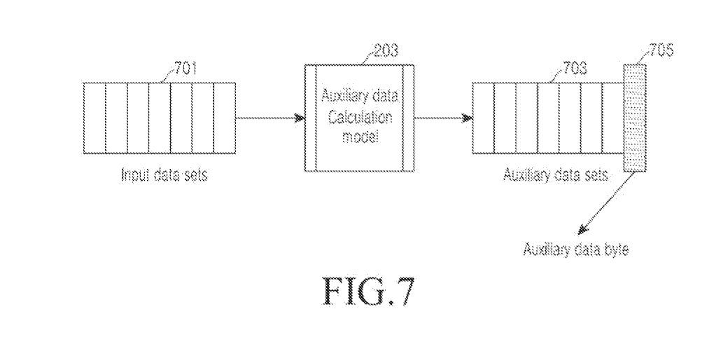

FIG. 7 is a block diagram illustrating an architecture of an auxiliary data calculation model, according to an embodiment of the present invention.

Referring to FIGS. 2 and 7, a target language is provided as input to a compression unit 103, which needs to be perfectly hashed. A scrambler 202 in the compression module divides the second/target language data into smaller data sets 701 of at least one character. The auxiliary data calculation model 203 calculates the auxiliary data as auxiliary data sets 703 based on number of bits in the string and length of the pattern/word. Further, the auxiliary data byte is appended at the end of each word as an auxiliary data byte 705 (e.g., having a size of 1 byte). Further, the auxiliary data sets for each target language character are distributed evenly based on their frequency of occurrence in a Minimal Perfect Hashing Function (MPHF) module 204. The scrambler 202 generates a 1: n mapping of base characters (the characters of the language for which an MPHF is designed) to the character set of second (target) language. Furthermore, the target language character set mapped to the MPHF is stored in the hash table 205.

Thus, for each item in the data set S, the auxiliary data byte is calculated prior to generating a hash value for the item.

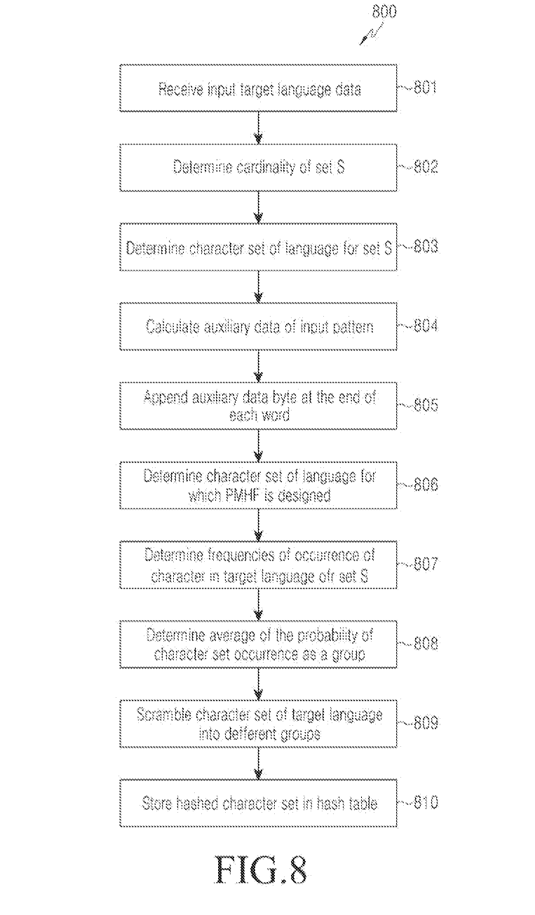

FIG. 8 is a flowchart illustrating a process of scrambling the characters of target language by utilizing auxiliary data, according to an embodiment of the present invention.

Referring to FIG. 8, a scrambler module receives an input target language, in step 801. The target language is divided into character set group S of at least one character for even distribution of characters. Further, Cardinality of set S (i.e., a total number of words that needs to be hashed) is determined, in step 802. Further, a character set of target language for set S is determined, in step 803. The auxiliary data calculation model calculates (804) the auxiliary data. Further, the auxiliary data byte is appended at the end of each word, in step 805. The character set of first (source) language for which MPHF is designed, is determined, in step 806. Further, the frequency of occurrence of characters in the target language for set S is determined, in step 807. The scrambler then intelligently scrambles the characters constituting the elements in set S. The Scrambling of character set is performed by averaging out the combined probability of character set occurrences as a group based on the cardinality of set S, such that each group of characters formed out of target language character set has an equal probability of occurrence, in step 808. The character set S of target language is scrambled into different groups corresponding to the character set of source language in which MPHF is defined, in step 809. Further, hashed character sets are stored in a hash table, in step 810. The various actions in the method 800 can be performed in the order presented, in a different order, or simultaneously. Further, in some embodiments of the present invention, some actions listed in FIG. 8 can be omitted.

According to another embodiment of the present invention, a separate database referred to as an auxiliary data set can be maintained. The auxiliary data set is formed based on the number of bits in the string and length of the pattern/word and reflects the value which is associated to each word/pattern in the data set S as calculated by auxiliary data calculation model.

According to another embodiment of the present invention, the auxiliary data can be stored based on the order of the hash values such as in ascending order, to achieve the lookup of auxiliary data for any given words in constant amount of time (i.e. O (1) time operation). Thus, there is a one-to-one correlation between the associated auxiliary data for a word/pattern and its corresponding hash value in the hash table.

To further enhance the false positive tolerance model, a separate automated learning of false-positives is also initiated so as to understand characteristics of false positives and absorb them in the main data set, if required. An identifier is used to distinguish between any of the false-positives from other elements in the main data set.

The embodiments of the present invention described herein can be implemented through at least one software program running on at least one hardware device and performing network management functions to control the network elements. The network elements shown in FIGS. 1, 2 and 7 include blocks that can be at least one of a hardware device, or a combination of hardware device and software module.

The embodiments of the present invention described herein provide methods and systems to enable customization of an application to enhance user experience on a computing device by having at least one resident client entity negotiate with at least one client execution entity or a server on aspects of said application that can be customized. Therefore, embodiments of the present invention may include such a program as well as a computer readable means having a message therein Such computer readable storage means may contain program code means for implementation of one or more steps of the method, when the program runs on a server or mobile device or any suitable programmable device. A method according to embodiments of the present invention may be implemented through or together with a software program written in a Very high speed integrated circuit Hardware Description Language (VHDL) or another programming language, or implemented by one or more VHDL or several software modules being executed on at least one hardware device. A hardware device according to an embodiment of the present invention can include any kind of portable device that can be programmed to perform operations according to embodiments of the present invention. The device can also include means including hardware means, such as an Application-Specific Integrated Circuit (ASIC), or a combination of hardware and software means, such as an ASIC and a Field-Programmable Gate Array (FPGA), or at least one microprocessor and at least one memory with software modules located therein. Methods according to embodiments of the present invention may be implemented partly in hardware and partly in software. Alternatively, the invention can be implemented on different hardware devices, e.g. using a plurality of Central Processing Units (CPUs).

While the present invention has been shown and described with reference to certain embodiments thereof, it will be understood by those skilled in the art that various changes in form and details may be made therein without departing from the spirit and scope of the present invention as defined by the appended claims and their equivalents.

What is claimed is:

1. A data compression method comprising:
selecting a Minimal Perfect Hashing Function (MPHF);
identifying a base character set for which the MPHF is designed;
identifying characters of a target character set; and
applying scrambling to distribute the characters of the target character set over the base character set.

2. The data compression method of claim 1, wherein the MPHF is selected independently of the base character set and the target character set.

3. The data compression method of claim 1, wherein applying the scrambling comprises applying the scrambling based on a cardinality of each group formed out of the target character set, such that characters of each group has an equal probability of occurrence.

4. The data compression method of claim 3, wherein the application of the scrambling is performed independently of the base character set and the target character set.

5. The data compression method of claim 3, wherein applying the scrambling comprises evenly distributing characters of the target character set over the base character set in the form of groups having at least one character.

6. The data compression method of claim 3, wherein applying the scrambling comprises one-to-one mapping the base character set to characters of the target character set, where the target character set is in the form of a group having at least one character.

7. The data compression method of claim 1, further comprising:
defining an auxiliary data byte for each character included in each group formed out of the target character set; and
appending the auxiliary data byte at an end of each character.

8. The data compression method of claim 7, wherein the auxiliary data byte is calculated based on the number of bits in a string representing each character included in each group and a length of each character.

9. The data compression method of claim 7, wherein the auxiliary data byte is stored in an ascending order based on hash values of each character included in each group.

10. A data compression system comprising:
a compression unit for selecting a Minimal Perfect Hashing Function (MPHF); and
a scrambler for identifying a base character set for which the MPHF is designed, identifying characters of a target character set, and distributing the characters of the target character set over the base character set.

11. The data compression system of claim 11, wherein the MPHF is selected independently of the base character set and the target character set.

12. The data compression system of claim 10, wherein the scrambler distributes the characters of the target character set over the base character set, based on a cardinality of each group formed out of the target character set, such that characters of each group has an equal probability of occurrence.

13. The data compression system of claim 12, wherein the scrambler distributes the characters of the target character set over the base character set, independently of the base character set and the target character set.

14. The data compression system of claim 12, wherein the scrambler evenly distributes characters of the target character set over the base character set in the form of groups having at least one character.

15. The data compression system of claim 12, wherein the scrambler one-to-one maps the base character set to characters of the target character set, where the target character set is in the form of a group having at least one character.

16. The data compression system of claim 10, further comprising an auxiliary data calculation model for defining an auxiliary data byte for each character included in each group formed out of the target character set and appending the auxiliary data byte at an end of each character.

17. The data compression system of claim 16, wherein the auxiliary data byte is calculated based on the number of bits in a string representing each character included in each group and a length of each character.

18. The data compression system of claim 16, wherein the auxiliary data byte is stored in an ascending order based on hash values of each character included in each group.
